(19) United States
(12) Patent Application Publication
(10) Pub. No.: US 2026/0280098 A1
(43) Pub. Date: Sep. 17, 2026

(54) ELECTRONIC DEVICE

(71) Applicant: Huawei Technologies Co., Ltd., Shenzhen (CN)

(72) Inventors: Ben Lai, Wuhan (CN); Siting Li, Wuhan (CN); Feng Tian, Wuhan (CN); Fan Cao, Wuhan (CN); Shijun Zhang, Wuhan (CN)

(21) Appl. No.: 19/669,512

(22) Filed: May 6, 2026

Related U.S. Application Data
(63) Continuation of application No. PCT/CN2025/087633, filed on Apr. 8, 2025.

(30) Foreign Application Priority Data
Apr. 30, 2024 (CN) 202410557549.4

(51) Int. Cl. H01Q 1/22; H01Q 1/02; H01Q 1/14; H01Q 1/38; H05K 1/02; H05K 1/14; H05K 1/189

(52) U.S. Cl. CPC H01Q 1/22; H01Q 1/02; H01Q 1/14; H01Q 1/38; H05K 1/0284; H05K 1/147; H05K 1/189; H05K 2201/056; H05K 2201/10128

(57) ABSTRACT

A rear cover is fastened to one side of a middle frame, and an inner cavity and an air duct are formed between the rear cover and the middle frame. Both a circuit board and a support member are mounted in the inner cavity. A first antenna sub-portion is fastened to one side of the support member and that faces the rear cover, and is electrically connected to the circuit board. A second antenna sub-portion is fastened to one side of the rear cover and that faces the middle frame, or is a part of the rear cover, and is at least partially located in the air duct. A region of the rear cover and that directly faces the second antenna sub-portion is a non-signal shielding region.

### CROSS-REFERENCE TO RELATED APPLICATIONS

This application is a continuation of International Application No. PCT/CN2025/087633, filed on Apr. 8, 2025, which claims priority to Chinese Patent Application No. 202410557549.4, filed on Apr. 30, 2024. The disclosures of the aforementioned applications are hereby incorporated by reference in their entireties.

### TECHNICAL FIELD

Embodiments of this application relate to the field of antenna technologies, and in particular, to an electronic device.

### BACKGROUND

Currently, for an electronic device that uses a large-sized bezel-less screen, a support antenna is usually used to implement signal transmission. However, due to a development requirement of multi-functionalization of the electronic device, there are a large quantity of internal components in the electronic device. Therefore, arrangement space of the support antenna in the electronic device is limited. Consequently, an area of the support antenna is limited, and performance of the antenna is poor.

### SUMMARY

An embodiment of this application provides an electronic device. An area of an antenna of the electronic device is large, and performance of the antenna is good.

According to a first aspect, an implementation of this application provides an electronic device, including a middle frame, a rear cover, a support member, a circuit board, a first antenna sub-portion, and a second antenna sub-portion. The rear cover is fastened to one side of the middle frame, and an inner cavity and an air duct are formed between the rear cover and the middle frame. Both the circuit board and the support member are mounted in the inner cavity. The first antenna sub-portion is fastened to one side that is of the support member and that faces the rear cover, and is electrically connected to the circuit board. The second antenna sub-portion is fastened to one side that is of the rear cover and that faces the middle frame, and is at least partially located in the air duct. A region that is of the rear cover and that directly faces the second antenna sub-portion is a non-signal shielding region. The non-signal shielding region allows a signal to pass through. The first antenna sub-portion and the second antenna sub-portion jointly form an antenna.

In this implementation, the antenna of the electronic device includes the first antenna sub-portion and the second antenna sub-portion. The second antenna sub-portion is additionally disposed in the electronic device, and the second antenna sub-portion is at least partially located in the air duct and can perform signal transmission through the rear cover, to increase an area of the antenna by using the air duct of the electronic device, so that performance of the antenna is improved, and the antenna has good bandwidth and radiation efficiency. In addition, the air duct of the electronic device also provides a good clearance environment for the antenna. This helps ensure performance of the antenna.

A feeding circuit is disposed on the circuit board, and the feeding circuit may feed the first antenna sub-portion. For example, the first antenna sub-portion may be electrically connected to the circuit board through a trace or a pin. For example, one end of the trace or the pin may be fastened to one side that is of the support member and that faces the rear cover, and is connected to the first antenna sub-portion, and the other end of the trace or the pin may be routed around a side surface of the support member to the circuit board, to be connected to the circuit board.

Air in the air duct can be exchanged with space outside the electronic device, to transfer heat inside the electronic device to the outside of the electronic device, to implement heat dissipation. For example, the air duct is isolated from the inner cavity. In this case, the air duct and the inner cavity are separated from each other, so that external dust, water vapor, and the like can be prevented from entering the inner cavity through the air duct, so as to protect a component located in the inner cavity and improve reliability of the electronic device.

The non-signal shielding region may be made of a non-conductive material. The non-conductive material may be fiberglass, ceramic, plastic, or the like.

In some possible implementations, the second antenna sub-portion is a flexible printed circuit board or a metal member. In this case, a structure of the second antenna sub-portion is simple and easy to implement.

In some possible implementations, the second antenna sub-portion is a conductive heat dissipation member. In this implementation, the electronic device reuses the heat dissipation member as the second antenna sub-portion, so that a heat dissipation function of the heat dissipation member can be retained, and the air duct can also take away heat of the heat dissipation member, so as to take away heat of another component that is in the electronic device and that is connected to the heat dissipation member in a thermally conductive manner, to ensure heat dissipation performance of the electronic device. In addition, performance of the antenna of the electronic device can be improved without adding an additional structural member, implementation difficulty is low, and costs are low.

For example, the second antenna sub-portion may be a graphite sheet. The graphite sheet is easy to be cut, meets a heat dissipation requirement and an antenna design requirement more easily, and has low costs. The graphite sheet may be assembled and fastened to the rear cover in a manner of bonding or the like.

In some possible implementations, the second antenna sub-portion is assembled and fastened to the rear cover. In this case, the second antenna sub-portion and the rear cover are first separately processed and then assembled, so that manufacturing difficulty is low, and implementation is easy. Alternatively, the second antenna sub-portion is formed on the rear cover. In this case, stability of a connection between the second antenna sub-portion and the rear cover is high. That is, the second antenna sub-portion may be fastened to the rear cover in an assembly and fastening manner or a forming manner.

In some possible implementations, the rear cover may be a non-metal rear cover, for example, a fiberglass rear cover, a ceramic rear cover, or a plastic rear cover. In this case, composition of the rear cover is simple and easy to implement.

In some possible implementation, an area of the second antenna sub-portion is greater than an area of the first antenna sub-portion. In this case, the second antenna sub-portion can greatly increase an area of the antenna of the electronic device, to improve performance of the antenna. For example, the area of the second antenna sub-portion may be greater than twice the area of the first antenna sub-portion.

In some possible implementations, the second antenna sub-portion is entirely disposed in correspondence with the air duct. In this case, the support member and the first antenna sub-portion may be disposed as close as possible to the air duct, to ensure coupling between the first antenna sub-portion and the second antenna sub-portion.

In some possible implementations, the second antenna sub-portion includes a first part and a second part, the first part is disposed in correspondence with the air duct, the second part is disposed in correspondence with the inner cavity, and an area of the first part is greater than an area of the second part. In this implementation, a large part of the structure of the second antenna sub-portion may be disposed in correspondence with the air duct, and a small part of the structure is located outside the air duct, so that difficulty of coupling the first antenna sub-portion and the second antenna sub-portion can be reduced, and space of the air duct can be fully used, to improve performance of the antenna of the electronic device.

In some possible implementations, a spacing between the first antenna sub-portion and the second antenna sub-portion is less than one eighth of a wavelength corresponding to a center frequency of an operating frequency band of the antenna. In this implementation, the spacing between the first antenna sub-portion and the second antenna sub-portion is set, so that the first antenna sub-portion and the second antenna sub-portion are close enough, and the first antenna sub-portion and the second antenna sub-portion can be smoothly coupled to jointly form the antenna.

In some possible implementations, the support member is an audio module, and the first antenna sub-portion is fastened to an acoustic chamber housing of the audio module. The audio module further includes a speaker mounted in the acoustic chamber housing. The first antenna sub-portion and the speaker of the audio module may be arranged in a staggered manner, to reduce interference caused by the speaker to the first antenna sub-portion.

In some possible implementations, the support member is a support, and the first antenna sub-portion is fastened to an insulation part of the support. At least a part of a structure of the support is made of an insulation material. For example, the support may be entirely made of an insulation material, and the insulation part of the support is the entire support; or the support may be partially made of an insulation material to form the insulation part, and the other part of the support may be a conductive part or another part.

In some possible implementations, the first antenna sub-portion is a flexible printed circuit board or a metal member. In this case, a structure of the first antenna sub-portion is simple and easy to implement.

In some possible implementations, the first antenna sub-portion is assembled and fastened to the support member. In this case, the first antenna sub-portion and the support member are first separately processed and then assembled, so that manufacturing difficulty is low, and implementation is easy. Alternatively, the first antenna sub-portion is formed on the support member. In this case, stability of a connection between the first antenna sub-portion and the support member is high.

In some possible implementations, a part of a structure of the support member forms a part of an air duct wall of the air duct. In this case, the support member and the air duct are arranged in a compact manner, and a distance between the support member and the air duct is very short. This facilitates coupling between the first antenna sub-portion and the second antenna sub-portion, and reduces difficulty in arranging the first antenna sub-portion and the second antenna sub-portion. In addition, this also helps save internal space of the electronic device, to facilitate miniaturization of the electronic device.

In some possible implementations, the electronic device further includes a first sealing member, and the first sealing member is located between the support member and the rear cover and forms a part of the air duct wall of an air duct. In this implementation, the first sealing member can seal the air duct and can also limit the support member and the rear cover to provide specific support for the rear cover. This helps improve structural reliability of the electronic device. In addition, the first sealing member is compressible to some extent and can absorb an assembly tolerance of the support member and the rear cover. This helps improve assembly precision of the electronic device.

In some possible implementations, the electronic device further includes a second sealing member, and the second sealing member is located between the support member and the middle frame and forms a part of the air duct wall of the air duct. In this implementation, the second sealing member can seal the air duct and can also limit the support member and the middle frame. This helps improve structural reliability of the electronic device. In addition, the second sealing member is compressible to some extent and can absorb an assembly tolerance of the support member and the middle frame. This helps improve assembly precision of the electronic device.

In some possible implementations, the middle frame includes a frame and a middle plate fastened to an inner side of the frame, the frame is connected to the rear cover, the middle plate and the rear cover are disposed opposite to each other, the air duct and the inner cavity are located between the middle plate and the rear cover, and an outlet of the air duct is disposed on the frame or disposed between the frame and the rear cover.

In some possible implementations, the middle plate includes an air duct bottom wall and an air duct side wall. The air duct side wall is fastened to one side that is of the air duct bottom wall and that faces the rear cover. The air duct side wall is connected to the rear cover. The air duct bottom wall, the air duct side wall, and the rear cover are disposed around the air duct. The air duct bottom wall and the air duct side wall are integrally formed on the middle plate. In other words, the air duct bottom wall and the air duct side wall may be formed together in a forming process of the middle plate, and the air duct bottom wall, the air duct side wall, and at least one other structure of the middle plate are integrally formed structural members.

In this implementation, the air duct side wall and the air duct bottom wall are integrally formed on the middle plate, so that a composition structure of the air duct can be simplified, airtightness of the air duct can be improved, difficulty in forming and assembling the air duct can be reduced, and costs of the electronic device can be reduced.

In some possible implementations, the middle plate includes a metal portion, and the metal portion is disposed directly opposite to the first antenna sub-portion and the second antenna sub-portion. For example, the middle plate may be entirely made of a metal material, to form the metal portion; or the middle plate may be partially made of a metal material, to form the metal portion.

In this implementation, the metal portion of the middle plate is disposed directly opposite to the first antenna sub-portion and the second antenna sub-portion and can be used as a reflection plate of the first antenna sub-portion and the second antenna sub-portion, to improve radiation efficiency of the antenna, adjust a signal direction of the antenna, and enhance signal strength of the antenna. In addition, the middle plate has the metal portion, so that structural strength of the middle frame can also be increased.

In some possible implementations, the electronic device further includes a fan, the fan is mounted in the inner cavity, and an air outlet of the fan communicates with the air duct. In this implementation, air formed by operation of the fan may be sent to the outside of the electronic device through the air duct, to take out heat inside the electronic device, to implement heat reduction.

In some possible implementations, the electronic device further includes a display, and the display is located on one side that is of the middle frame and that faces away from the rear cover, and is fastened to the middle frame. For example, the display has a display function, or the display may integrate a display function and a touch sensing function.

According to a second aspect, an implementation of this application provides an electronic device, including a middle frame, a rear cover, a circuit board, a support member, and a first antenna sub-portion. The rear cover is fastened to one side of the middle frame, an inner cavity and an air duct are formed between the rear cover and the middle frame, both the circuit board and the support member are mounted in the inner cavity, and the first antenna sub-portion is fastened to one side that is of the support member and that faces the rear cover, and is electrically connected to the circuit board.

The rear cover includes a main body and a second antenna sub-portion connected to the main body. An arrangement surface of the main body and the second antenna sub-portion is perpendicular to a thickness direction of the rear cover, and the main body and the second antenna sub-portion are insulated from each other. At least a part of the second antenna sub-portion is disposed directly opposite to the air duct. The first antenna sub-portion and the second antenna sub-portion jointly form an antenna.

In this implementation, the antenna of the electronic device includes the first antenna sub-portion and the second antenna sub-portion. The second antenna sub-portion is additionally disposed in the electronic device, the second antenna sub-portion is a part of a structure of the rear cover and can perform signal transmission with the outside, and at least a part of the second antenna sub-portion is disposed in correspondence with the air duct, so that an area of the antenna is increased by using the air duct of the electronic device, performance of the antenna is improved, and the antenna has good bandwidth and radiation efficiency. In addition, the air duct of the electronic device also provides a good clearance environment for the antenna. This helps ensure performance of the antenna.

Air in the air duct can be exchanged with space outside the electronic device, to transfer heat inside the electronic device to the outside of the electronic device, to implement heat dissipation. For example, the air duct is isolated from the inner cavity. In this case, the air duct and the inner cavity are separated from each other, so that external dust, water vapor, and the like can be prevented from entering the inner cavity through the air duct, so as to protect a component located in the inner cavity and improve reliability of the electronic device.

In some possible implementations, the second antenna sub-portion is made of a conductive material. In this embodiment, a part of a region of the rear cover is made of a conductive material, to form a conductive second antenna sub-portion, so that the second antenna sub-portion can be used as a part of the antenna. The conductive material may be a metal, a carbon fiber, or the like.

In some possible implementations, the main body includes an insulation portion and a conductive portion, the insulation portion is connected between the second antenna sub-portion and the conductive portion, and a material of the conductive portion is the same as or different from the material of the second antenna sub-portion.

When the material of the conductive portion is the same as the material of the second antenna sub-portion, the rear cover may use a structure in which a slit is formed in a conductive structure, and the slit is filled with a non-conductive structure. In this case, manufacturing costs of the rear cover are low. When the material of the conductive portion is different from the material of the second antenna sub-portion, the material of the second antenna sub-portion is selected more flexibly and can better adapt to an antenna signal transmission requirement.

In some possible implementations, the main body is made of an insulation material. In this case, the rear cover may use a structure in which a localized conductive structure is added to an insulation structure.

In some possible implementation, an area of the second antenna sub-portion is greater than an area of the first antenna sub-portion. In this case, the second antenna sub-portion can greatly increase an area of the antenna of the electronic device, to improve performance of the antenna. For example, the area of the second antenna sub-portion may be greater than twice the area of the first antenna sub-portion.

In some possible implementations, the second antenna sub-portion is entirely disposed in correspondence with the air duct. In this case, the support member and the first antenna sub-portion may be disposed as close as possible to the air duct, to ensure coupling between the first antenna sub-portion and the second antenna sub-portion.

In some possible implementations, the second antenna sub-portion includes a first part and a second part, the first part is disposed in correspondence with the air duct, the second part is disposed in correspondence with the inner cavity, and an area of the first part is greater than an area of the second part. In this implementation, a large part of the structure of the second antenna sub-portion may be disposed in correspondence with the air duct, and a small part of the structure is located outside the air duct, so that difficulty of coupling the first antenna sub-portion and the second antenna sub-portion can be reduced, and space of the air duct can be fully used, to improve performance of the antenna of the electronic device.

In some possible implementations, a spacing between the first antenna sub-portion and the second antenna sub-portion is less than one eighth of a wavelength corresponding to a center frequency of an operating frequency band of the antenna. In this implementation, the spacing between the first antenna sub-portion and the second antenna sub-portion is set, so that the first antenna sub-portion and the second antenna sub-portion are close enough, and the first antenna sub-portion and the second antenna sub-portion can be smoothly coupled to jointly form the antenna.

In some possible implementations, the support member is an audio module, and the first antenna sub-portion is fastened to an acoustic chamber housing of the audio module. The audio module further includes a speaker mounted in the acoustic chamber housing. The first antenna sub-portion and the speaker of the audio module may be arranged in a staggered manner, to reduce interference caused by the speaker to the first antenna sub-portion.

In some possible implementations, the support member is a support, and the first antenna sub-portion is fastened to an insulation part of the support.

In some possible implementations, the first antenna sub-portion is a flexible printed circuit board or a metal member. In this case, a structure of the first antenna sub-portion is simple and easy to implement.

In some possible implementations, the first antenna sub-portion is assembled and fastened to the support member. In this case, the first antenna sub-portion and the support member are first separately processed and then assembled, so that manufacturing difficulty is low, and implementation is easy. Alternatively, the first antenna sub-portion is formed on the support member. In this case, stability of a connection between the first antenna sub-portion and the support member is high.

In some possible implementations, a part of a structure of the support member forms a part of an air duct wall of the air duct. In this case, the support member and the air duct are arranged in a compact manner, and a distance between the support member and the air duct is very short. This facilitates coupling between the first antenna sub-portion and the second antenna sub-portion, and reduces difficulty in arranging the first antenna sub-portion and the second antenna sub-portion. In addition, this also helps save internal space of the electronic device, to facilitate miniaturization of the electronic device.

In some possible implementations, the electronic device further includes a first sealing member, and the first sealing member is located between the support member and the rear cover and forms a part of the air duct wall of an air duct. In this implementation, the first sealing member can seal the air duct and can also limit the support member and the rear cover to provide specific support for the rear cover. This helps improve structural reliability of the electronic device. In addition, the first sealing member is compressible to some extent and can absorb an assembly tolerance of the support member and the rear cover. This helps improve assembly precision of the electronic device.

In some possible implementations, the electronic device further includes a second sealing member, and the second sealing member is located between the support member and the middle frame and forms a part of the air duct wall of the air duct. In this implementation, the second sealing member can seal the air duct and can also limit the support member and the middle frame. This helps improve structural reliability of the electronic device. In addition, the second sealing member is compressible to some extent and can absorb an assembly tolerance of the support member and the middle frame. This helps improve assembly precision of the electronic device.

In some possible implementations, the middle frame includes a frame and a middle plate fastened to an inner side of the frame, the frame is connected to the rear cover, the middle plate and the rear cover are disposed opposite to each other, the air duct and the inner cavity are located between the middle plate and the rear cover, and an outlet of the air duct is disposed on the frame or disposed between the frame and the rear cover.

In some possible implementations, the middle plate includes an air duct bottom wall and an air duct side wall. The air duct side wall is fastened to one side that is of the air duct bottom wall and that faces the rear cover. The air duct side wall is connected to the rear cover. The air duct bottom wall, the air duct side wall, and the rear cover are disposed around the air duct. The air duct bottom wall and the air duct side wall are integrally formed on the middle plate. In other words, the air duct bottom wall and the air duct side wall may be formed together in a forming process of the middle plate, and the air duct bottom wall, the air duct side wall, and at least one other structure of the middle plate are integrally formed structural members.

In this implementation, the air duct side wall and the air duct bottom wall are integrally formed on the middle plate, so that a composition structure of the air duct can be simplified, airtightness of the air duct can be improved, difficulty in forming and assembling the air duct can be reduced, and costs of the electronic device can be reduced.

In some possible implementations, the middle plate includes a metal portion, and the metal portion is disposed directly opposite to the first antenna sub-portion and the second antenna sub-portion. For example, the middle plate may be entirely made of a metal material, to form the metal portion; or the middle plate may be partially made of a metal material, to form the metal portion.

In this implementation, the metal portion of the middle plate is disposed directly opposite to the first antenna sub-portion and the second antenna sub-portion and can be used as a reflection plate of the first antenna sub-portion and the second antenna sub-portion, to improve radiation efficiency of the antenna, adjust a signal direction of the antenna, and enhance signal strength of the antenna. In addition, the middle plate has the metal portion, so that structural strength of the middle frame can also be increased.

In some possible implementations, the electronic device further includes a fan, the fan is mounted in the inner cavity, and an air outlet of the fan communicates with the air duct. In this implementation, air formed by operation of the fan may be sent to the outside of the electronic device through the air duct, to take out heat inside the electronic device, to implement heat reduction.

In some possible implementations, the electronic device further includes a display, and the display is located on one side that is of the middle frame and that faces away from the rear cover, and is fastened to the middle frame. For example, the display has a display function, or the display may integrate a display function and a touch sensing function.

### BRIEF DESCRIPTION OF THE DRAWINGS

To describe technical solutions in embodiments of this application or in the background, the following describes the accompanying drawings used in embodiments of this application or the background.

FIG. 1 is a diagram of a structure of an electronic device according to an embodiment of this application;

FIG. 2 is a diagram of a part of a structure of the electronic device shown in FIG. 1;

FIG. 3 is a diagram of a cross-sectional structure that is of the electronic device shown in FIG. 1 and that is cut along A-A;

FIG. 4 is a partially enlarged diagram of the structure shown in FIG. 3;

FIG. 5 is a diagram of comparison between S11 curves of antennas of an electronic device according to an embodiment of this application and a conventional electronic device;

FIG. 6 is a diagram of comparison between radiation efficiency curves of antennas of an electronic device according to an embodiment of this application and a conventional electronic device;

FIG. 7 is a diagram of a partial structure of an electronic device according to an embodiment of this application in some other embodiments; and

FIG. 8 is a diagram of a structure of a rear cover of the electronic device shown in FIG. 7 at another angle.

### DETAILED DESCRIPTION OF ILLUSTRATIVE EMBODIMENTS

The following describes embodiments of this application with reference to the accompanying drawings in embodiments of this application.

In descriptions of embodiments of this application, it should be noted, unless otherwise explicitly specified and limited, that terms "mounting" and "connection" should be understood in a broad sense. For example, "connection" may be a detachable connection, a non-detachable connection, a direct connection, or an indirect connection through an intermediate medium.

Terms "first", "second", and the like in embodiments of this application are merely intended for a purpose of description, and shall not be understood as an indication or implication of relative importance or implicit indication of a quantity of indicated technical features. Therefore, a feature limited by "first", "second", or the like may explicitly or implicitly include one or more features. The term "a plurality of" means at least two. The terms "include", "have", and their variants all mean "include but are not limited to", unless otherwise specifically emphasized in another manner. The "integrally formed structural member" means that in a process of forming one part of the structural member, the part is connected to another part, and the two parts do not need to be connected by reprocessing (for example, bonding, welding, fastener connection, or screw connection).

The term "and/or" in embodiments of this application describes only an association relationship between associated objects and represents that three relationships may exist. For example, A and/or B may represent the following three cases: Only A exists, both A and B exist, and only B exists. In addition, the character "/" in this specification generally indicates an "or" relationship between the associated objects.

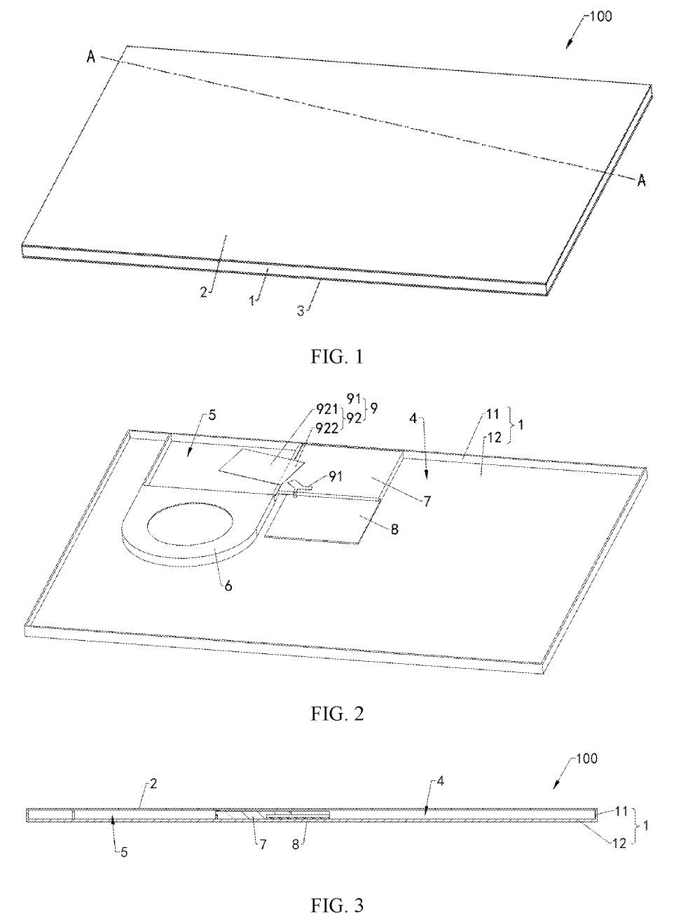

FIG. 1 is a diagram of a structure of an electronic device 100 according to an embodiment of this application, and FIG. 2 is a diagram of a part of a structure of the electronic device 100 shown in FIG. 1.

In some embodiments, the electronic device 100 in this embodiment of this application may be an electronic product such as a tablet computer, a notebook computer, a mobile phone, or a wearable device, and the wearable device may be a smartwatch, a smart band, smart glasses, or the like. The electronic device 100 may be a bar-type device or a foldable device. The electronic device 100 in this embodiment of this application is described by using a tablet computer as an example. Certainly, another type of electronic device 100 may also use a similar structure. Details are not described again below. It should be noted that FIG. 1 and the following related accompanying drawings schematically show only some components included in the electronic device 100. Actual shapes, actual sizes, actual locations, and actual structures of these components are not limited to those in FIG. 1 and the following accompanying drawings.

In some embodiments, the electronic device 100 may include a middle frame 1, a rear cover 2, and a display 3. For example, the rear cover 2 is fastened to one side of the middle frame 1, and the display 3 is located on one side that is of the middle frame 1 and that faces away from the rear cover 2, and is fastened to the middle frame 1. For ease of description, the electronic device 100 is defined to have a thickness direction, and the rear cover 2, the middle frame 1, and the display 3 are defined to be arranged in the thickness direction of the electronic device 100. In some examples, entirety or main parts of the rear cover 2 and the display 3 may be in a flat shape, and are perpendicular to the thickness direction of the electronic device 100.

For example, the display 3 has a display function, or the display 3 may integrate a display function and a touch sensing function. The display function of the display 3 is configured to display text, an image, a video, and the like. The touch sensing function of the display 3 is used to detect a touch action of a user, to implement human-machine information interaction. The display 3 may be an organic light-emitting diode (OLED) display, an active matrix organic light-emitting diode (AMOLED) display, a mini organic light-emitting diode display, a micro light-emitting diode (Micro LED) display, a micro organic light-emitting diode (Micro OLED) display, a quantum dot light-emitting diode (QLED) display, a liquid crystal display (LCD), or the like. In some other embodiments, alternatively, the display 3 may not be disposed on the electronic device 100.

For example, the middle frame 1 may include a frame 11 and a middle plate 12 fastened on an inner side of the frame 11, the frame 11 is connected to the rear cover 2, and the middle plate 12 and the rear cover 2 are disposed opposite to each other. The frame 11 and the middle plate 12 may be integrally formed structural members, or may form an integrated structure in an assembly manner, for example, in a manner of bonding, welding, clamping, or fastening connection. This is not strictly limited in this embodiment of this application.

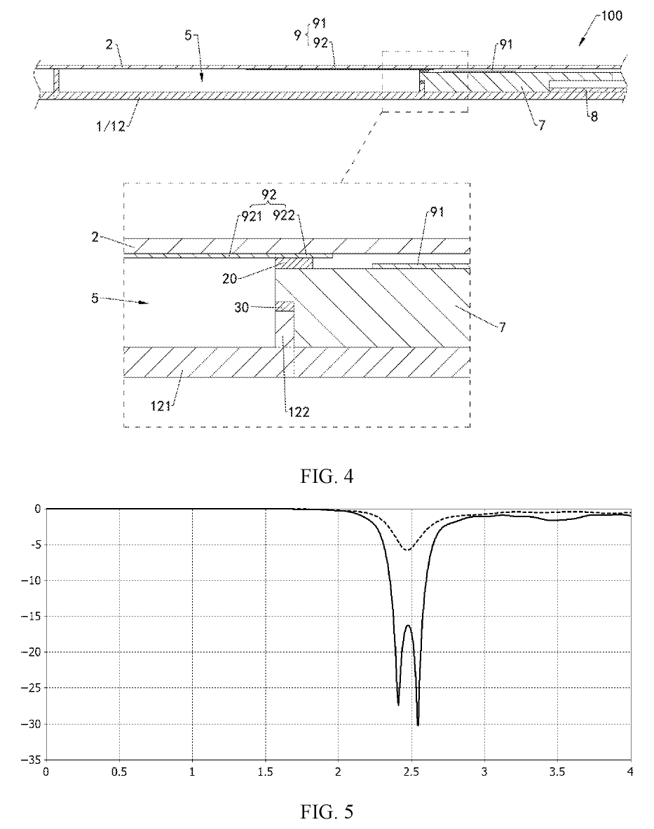

Refer to FIGS. 2-4. FIG. 3 is a diagram of a cross-sectional structure that is of the electronic device 100 shown in FIG. 1 and that is cut along A-A, and FIG. 4 is a partially enlarged diagram of the structure shown in FIG. 3.

In some embodiments, an inner cavity 4 and an air duct 5 are formed between the rear cover 2 and the middle frame 1. For example, the air duct 5 and the inner cavity 4 may be located between the middle plate 12 and the rear cover 2. The inner cavity 4 is located on an inner side of the frame 11. An outlet (not shown in the figure) of the air duct 5 may be disposed on the frame 11 or disposed between the frame 11 and the rear cover 2. Air in the air duct 5 can be exchanged with air outside the electronic device 100, to transfer heat inside the electronic device 100 to the outside of the electronic device 100, to implement heat dissipation. For example, the air duct 5 is isolated from the inner cavity 4. In this case, the air duct band the inner cavity 4 are separated from each other and are mutually independent space, so that external dust, water vapor, and the like can be prevented from entering the inner cavity 4 through the air duct 5, so as to protect a component located in the inner cavity 4 and improve reliability of the electronic device 100.

For example, the middle plate 12 may include an air duct bottom wall 121 and an air duct side wall 122. The air duct side wall 122 is fastened to one side that is of the air duct bottom wall 121 and that faces the rear cover 2. The air duct side wall 122 is connected to the rear cover 2. The air duct bottom wall 121, the air duct side wall 122, and the rear cover 2 are disposed around the air duct 5. The air duct bottom wall 121 and the air duct side wall 122 may be integrally formed on the middle plate 12. In other words, the air duct bottom wall 121 and the air duct side wall 122 may be formed together in a forming process of the middle plate 12, and the air duct bottom wall 121, the air duct side wall 122, and at least one other structure of the middle plate 12 are integrally formed structural members. For example, the middle plate 12 may be formed through die-casting, and in a die-casting forming process, the air duct bottom wall 121 and the air duct side wall 122 are formed together.

In this embodiment, the air duct side wall 122 and the air duct bottom wall 121 are integrally formed on the middle plate 12, so that a composition structure of the air duct 5 can be simplified, airtightness of the air duct 5 can be improved, difficulty in forming and assembling the air duct 5 can be reduced, and costs of the electronic device 100 can be reduced.

In some other embodiments, the air duct side wall 122 and the air duct bottom wall 121 may alternatively be independently formed and then fastened to another structure of the middle plate 12 through assembly, to form a part of the middle plate 12. In embodiments of this application, "assembly and fastening" means performing fastening in an assembly manner, for example, performing fastening in a manner of welding, clamping, bonding, or fastener connection.

In some embodiments, the electronic device 100 further includes a fan 6. The fan 6 is mounted in the inner cavity 4, and an air outlet of the fan 6 communicates with the air duct 5. In this embodiment, air formed by operation of the fan 6 may be sent to the outside of the electronic device 100 through the air duct 5, to take out heat inside the electronic device 100, to implement heat reduction. In some examples, the air duct side wall 122 may include two parts disposed opposite to each other, one end of the two parts may be connected to the frame 11, and the other end of the two parts may be connected to the fan 6.

It may be understood that, in this embodiment of this application, the electronic device 100 may be a thin product with a large planar size. For example, the planar size may be 10 inches (25.4 cm) or greater. In this case, the display 3 may also be a product with a large planar size, to implement large-screen display. In addition, there is sufficient space inside the electronic device 100 for disposing the air duct 5 and the fan 6, so that the electronic device 100 has good heat dissipation performance.

In some other embodiments, it is alternatively possible to dispose the air duct 5 in the electronic device 100 without disposing the fan 6, air exchange is performed with the outside of the electronic device 100 through the air duct 5, and heat in the electronic device 100 can also be taken away, to implement heat dissipation. Alternatively, another structural member may alternatively be disposed in the electronic device 100, to perform heat exchange with the outside of the electronic device 100 through the air duct 5 or drive air in the air duct 5 to perform heat exchange with the outside of the electronic device 100. This is not strictly limited in this embodiment of this application.

Refer to FIGS. 2 and 3. In some embodiments, the electronic device 100 may further include a support member 7, and the support member 7 is mounted in the inner cavity 4. The support member 7 may be disposed adjacent to the air duct 5 to be close to the air duct 5. For example, the support member 7 may be fastened to one side that is of the middle plate 12 and that faces the rear cover 2. The support member 7 has a specific structural height, and there may be a gap between the support member 7 and the rear cover 2, but the gap is obviously smaller than a gap between the middle plate 12 and the rear cover 2.

In some examples, the support member 7 may be an audio module. For example, the audio module may have an acoustic chamber housing and a speaker, and the speaker may be mounted on an inner side of the acoustic chamber housing. The acoustic chamber housing may be entirely made of an insulation material, for example, plastic, and an insulation part of the acoustic chamber housing is an entire support. Alternatively, the acoustic chamber housing may be partially made of a non-metal material, and this part forms an insulation part of the acoustic chamber housing.

In some other examples, the support member 7 may be a support. At least a part of a structure of the support is made of an insulation material. For example, the support may be entirely made of an insulation material, and an insulation part of the support is the entire support; or the support may be partially made of an insulation material to form an insulation part, and the other part of the support may be a conductive part or another part. The insulation material may be plastic or the like.

In some embodiments, the electronic device 100 may further include a circuit board 8, and the circuit board 8 is mounted in the inner cavity 4. The circuit board 8 may be disposed adjacent to the support member 7 to be close to the support member 7. The circuit board 8 may be a rigid printed circuit board (PCB), a flexible printed circuit board (FPC), or a rigid-flex printed circuit board. This is not strictly limited in this embodiment of this application.

Refer to FIGS. 2 and 4. In some embodiments, the electronic device 100 may further include a first antenna sub-portion 91. The first antenna sub-portion 91 is fastened to one side that is of the support member 7 and that faces the rear cover 2, and is electrically connected to the circuit board 8. A feeding circuit (not shown in the figure) is disposed on the circuit board 8, and the feeding circuit may feed the first antenna sub-portion 91. For example, the first antenna sub-portion 91 may be electrically connected to the circuit board 8 through a trace or a pin. For example, one end of the trace or the pin may be fastened to one side that is of the support member 7 and that faces the rear cover 2, and is connected to the first antenna sub-portion 91, and the other end of the trace or the pin may be routed around a side surface of the support member 7 to the circuit board 8, to be connected to the circuit board 8.

For example, when the support member 7 is the audio module, the first antenna sub-portion 91 may be fastened to the acoustic chamber housing of the audio module, for example, fastened to the insulation part of the acoustic chamber housing. The first antenna sub-portion 91 and the speaker (not shown in the figure) of the audio module may be arranged in a staggered manner, to reduce interference caused by the speaker to the first antenna sub-portion 91.

For example, when the support member 7 is the support, the first antenna sub-portion 91 may be fastened to the insulation part of the support.

For example, the first antenna sub-portion 91 may be a flexible printed circuit board or a metal member. In this case, a structure of the first antenna sub-portion 91 is simple and easy to implement.

For example, the first antenna sub-portion 91 may be assembled and fastened to the support member 7. In this case, the first antenna sub-portion 91 and the support member 7 are first separately processed and then assembled, so that manufacturing difficulty is low, and implementation is easy. Alternatively, the first antenna sub-portion 91 may be formed on the support member 7. In this case, stability of a connection between the first antenna sub-portion 91 and the support member 7 is high. That is, the first antenna sub-portion 91 may be fastened to the support member 7 in an assembly and fastening manner or a forming manner.

For example, the first antenna sub-portion 91 is a flexible printed circuit board, and the first antenna sub-portion 91 is assembled and fastened to the support member 7 in a manner of bonding, clamping, welding, fastener connection, or the like. Alternatively, the first antenna sub-portion 91 is a metal plate, for example, may be a copper plate, an iron plate, or an aluminum plate, and may be assembled and fastened to the support member 7 in a manner of bonding, clamping, welding, fastener connection, or the like. Alternatively, the first antenna sub-portion 91 is an LDS (Laser-Direct-structuring) metal structural member and may be made of a metal material such as copper, iron, or aluminum, and the first antenna sub-portion 91 may be directly formed on the support member 7 by using an LDS process.

Refer to FIGS. 2 and 4. In some embodiments, the electronic device 100 may further include a second antenna sub-portion 92. The second antenna sub-portion 92 may be fastened to one side that is of the rear cover 2 and that faces the middle frame 1, and is at least partially located in the air duct 5. The second antenna sub-portion 92 may form a first projection on the rear cover 2, and the air duct 5 may form a second projection on the rear cover 2. When the first projection is at least partially located in the second projection, that is, when the first projection at least partially overlaps the second projection, the second antenna sub-portion 92 is at least partially located in the air duct 5.

A region that is of the rear cover 2 and that faces the second antenna sub-portion 92 is a non-signal shielding region. The non-signal shielding region allows a signal to pass through, and may also be referred to as a signal passing region. For example, the non-signal shielding region may be made of a non-conductive material. The non-conductive material may be fiberglass, ceramic, plastic, or the like.

In some examples, the rear cover 2 may be a non-metal rear cover, for example, a fiberglass rear cover, a ceramic rear cover, or a plastic rear cover. In this case, composition of the rear cover 2 is simple and easy to implement. In some other examples, the rear cover 2 may alternatively be a splicing structure. For example, when the rear cover 2 includes the non-signal shielding region (a first region for short), the rear cover 2 may further include a second region. The second region may be a signal shielding region or a non-signal shielding region, and the second region is spliced with the first region. A specific structure and a material of the rear cover 2 are not strictly limited in this embodiment of this application.

The first antenna sub-portion 91 is coupled to the second antenna sub-portion 92. The first antenna sub-portion 91 and the second antenna sub-portion 92 jointly form an antenna 9 of the electronic device 100. That is, the antenna 9 of the electronic device 100 includes the first antenna sub-portion 91 and the second antenna sub-portion 92.

In this embodiment, the second antenna sub-portion 92 is additionally disposed in the antenna 9 of the electronic device 100, and the second antenna sub-portion 92 is at least partially located in the air duct 5 and can perform signal transmission through the rear cover 2, to increase an area of the antenna 9 by using the air duct 5 of the electronic device 100, so that performance of the antenna 9 is improved, and the antenna 9 has good bandwidth and radiation efficiency. In addition, the air duct 5 of the electronic device 100 also provides a good clearance environment for the antenna 9. This helps ensure performance of the antenna 9.

In this embodiment of this application, because the antenna 9 includes both the first antenna sub-portion 91 and the second antenna sub-portion 92, the first antenna sub-portion 91 and the second antenna sub-portion 92 operate at the same time to present performance of the antenna 9. If the second antenna sub-portion 92 is omitted, an S11 curve of the antenna and a frequency curve of the antenna change obviously.

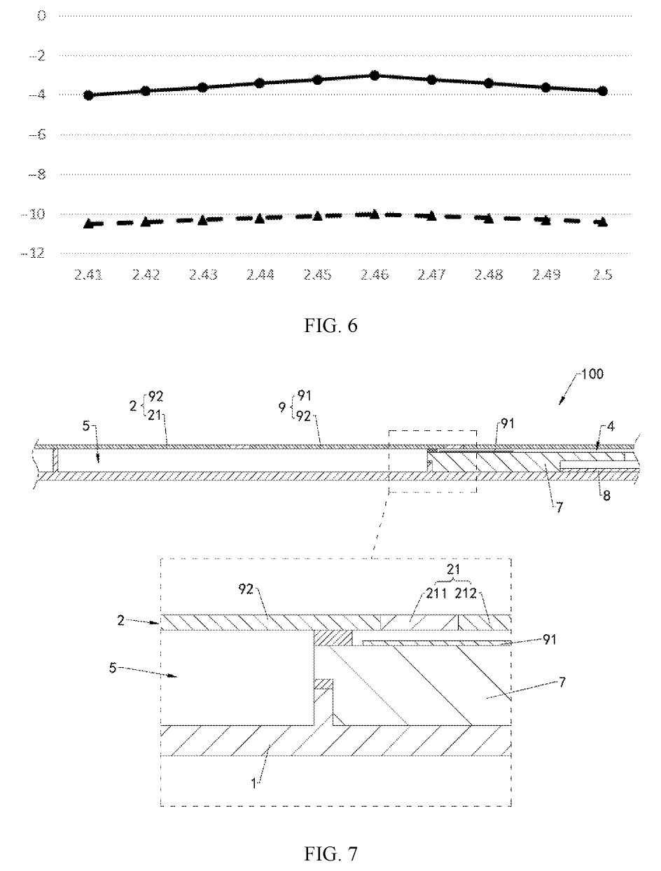

FIG. 5 is a diagram of comparison between S11 curves of antennas of the electronic device 100 according to an embodiment of this application and a conventional electronic device 100, and FIG. 6 is a diagram of comparison between radiation efficiency curves of antennas of the electronic device 100 according to an embodiment of this application and a conventional electronic device 100.

In FIG. 5, an S11 curve represents a return loss of an antenna, a vertical coordinate is in a unit of decibel (dB), and a horizontal coordinate represents a frequency and is in a unit of GHz. In FIG. 5, a solid line represents an S11 curve of the antenna 9 of the electronic device 100 in this embodiment of this application, and a dashed curve represents an S11 curve of an antenna on which no second antenna sub-portion 92 is disposed. It can be learned from FIG. 5 that, in some possible embodiments, the electronic device 100 in this embodiment of this application can implement coverage of a 2.4 GHz frequency band of Wi-Fi (Wireless Fidelity), and a resonance depth is significantly improved compared with a solution in which the second antenna sub-portion 92 is not disposed.

In FIG. 6, the unit of the vertical coordinate is decibel (dB), and the horizontal coordinate represents a frequency and is in a unit of GHz. In FIG. 5, a solid line represents a radiation efficiency curve of the antenna 9 of the electronic device 100 in this embodiment of this application, and a dashed curve with triangles represents a radiation efficiency curve of an antenna on which no second antenna sub-portion 92 is disposed. It can be learned from FIG. 6 that, in some possible embodiments, radiation efficiency of the electronic device 100 in this embodiment of this application on a 2.4 GHz frequency band is improved by about 6 dB compared with a solution in which the second antenna sub-portion 92 is not disposed.

It may be understood that, the second antenna sub-portion 92 is disposed to add an in-band resonance, and the second antenna sub-portion 92 is a main radiator of the antenna 9, so that performance of the antenna 9 of the electronic device 100 is improved. In some examples, the first antenna sub-portion 91 may form a resonance, and the resonance may be located in a band or not located in a band. Alternatively, the first antenna sub-portion 91 may not form a resonance. The first antenna sub-portion 91 is configured to feed a signal into the second antenna sub-portion 92. A specific function and a composition of the first antenna sub-portion 91 are not strictly limited in this embodiment of this application.

It may be understood that, in addition to the 2.4 GHz frequency band of Wi-Fi, in some other embodiments, the antenna 9 of the electronic device 100 in this embodiment of this application may also cover another frequency band, for example, may cover another frequency band within 1.7 GHz to 5 GHz.

In this embodiment of this application, the second antenna sub-portion 92 may include one or more structural members. When the second antenna sub-portion 92 includes a plurality of structural members, the plurality of structural members may be arranged in a connected manner or spaced apart. A specific composition and a shape of the second antenna sub-portion are not strictly limited in this embodiment of this application. The following embodiment is described by using an example in which the second antenna sub-portion 92 includes one structural member.

Refer to FIGS. 2 and 4 again. In some embodiments, an area of the second antenna sub-portion 92 is greater than an area of the first antenna sub-portion 91. In this case, the second antenna sub-portion 92 can greatly increase the area of the antenna 9 of the electronic device 100, to improve performance of the antenna 9. For example, the area of the second antenna sub-portion 92 may be greater than twice the area of the first antenna sub-portion 91.

Because space of the air duct 5 of the electronic device 100 is large, the second antenna sub-portion 92 can be disposed with a large area, to make full use of the space of the air duct 5, so that performance of the antenna 9 is better.

In some embodiments, the second antenna sub-portion 92 may include a first part 921 and a second part 922. The second part 922 is connected to the first part 921. The first part 921 is disposed in correspondence with the air duct 5, for example, may be located in the air duct 5. The second part 922 is disposed in correspondence with the inner cavity 4, for example, may be located outside the air duct 5. An area of the first part 921 is greater than an area of the second part 922.

In this embodiment, a large part of a structure of the second antenna sub-portion 92 may be disposed in correspondence with the air duct 5, and a small part of the structure is located outside the air duct 5, so that difficulty of coupling the first antenna sub-portion 91 and the second antenna sub-portion 92 can be reduced, and the space of the air duct 5 can be fully used, to improve performance of the antenna 9 of the electronic device 100.

In some other embodiments, the second antenna sub-portion 92 may alternatively be entirely disposed in correspondence with the air duct 5. For example, the second antenna sub-portion 92 may be entirely located in the air duct 5. In this case, the support member 7 and the first antenna sub-portion 91 may be disposed as close as possible to the air duct 5, to ensure coupling between the first antenna sub-portion 91 and the second antenna sub-portion 92.

In some embodiments, a spacing between the first antenna sub-portion 91 and the second antenna sub-portion 92 is less than one eighth of a wavelength corresponding to a center frequency of an operating frequency band of the antenna 9. Because shapes of the second antenna sub-portion 92 and the first antenna sub-portion 91 may be regular or irregular shapes, the spacing between the first antenna sub-portion 91 and the second antenna sub-portion 92 means a size at a narrowest location in a gap between the first antenna sub-portion 91 and the second antenna sub-portion 92.

In this embodiment, the spacing between the first antenna sub-portion 91 and the second antenna sub-portion 92 is set, so that the first antenna sub-portion 91 and the second antenna sub-portion 92 are close enough, and the first antenna sub-portion 91 and the second antenna sub-portion 92 can be smoothly coupled to jointly form the antenna 9. It may be understood that, in some other embodiments, when the first antenna sub-portion 91 and the second antenna sub-portion 92 are coupled, the spacing between the first antenna sub-portion 91 and the second antenna sub-portion 92 may alternatively meet another setting. This is not strictly limited in this embodiment of this application.

In some examples, in a thickness direction of the electronic device 100, the second antenna sub-portion 92 and the first antenna sub-portion 91 may be disposed in a staggered manner. In some other examples, in the thickness direction of the electronic device 100, the second antenna sub-portion 92 and the first antenna sub-portion 91 may be disposed at least partially directly opposite to each other. A relative location relationship between the second antenna sub-portion 92 and the first antenna sub-portion 91 is not strictly limited in this embodiment of this application.

In some embodiments, the second antenna sub-portion 92 may be a flexible printed circuit board or a metal member. In this case, a structure of the second antenna sub-portion 92 is simple and easy to implement. For example, the second antenna sub-portion 92 may be assembled and fastened to the rear cover 2. In this case, the second antenna sub-portion 92 and the rear cover 2 are first separately processed and then assembled, so that manufacturing difficulty is low, and implementation is easy. Alternatively, the second antenna sub-portion 92 may be formed on the rear cover 2. For example, after the rear cover 2 is manufactured, the second antenna sub-portion 92 may be processed and manufactured on the rear cover 2, so that the second antenna sub-portion 92 is directly formed on the rear cover 2 and does not need to be fastened to the rear cover 2 through a subsequent assembly process. In this case, stability of a connection between the second antenna sub-portion 92 and the rear cover 2 is high. In this embodiment of this application, the second antenna sub-portion 92 may be fastened to the rear cover 2 in an assembly and fastening manner or a forming manner, so that implementations are flexible and diversified.

For example, the second antenna sub-portion 92 is a flexible printed circuit board, and the second antenna sub-portion 92 is assembled and fastened to the rear cover 2 in a manner of bonding, clamping, welding, fastener connection, or the like. Alternatively, the second antenna sub-portion 92 is a metal plate, for example, may be a copper plate, an iron plate, or an aluminum plate, and may be assembled and fastened to the rear cover 2 in a manner of bonding, clamping, welding, fastener connection, or the like. Alternatively, the second antenna sub-portion 92 is an LDS (Laser-Direct-structuring) metal structural member and may be made of a metal material such as copper, iron, or aluminum, and the second antenna sub-portion 92 may be directly formed on the rear cover 2 by using an LDS process. When the second antenna sub-portion 92 is a flexible printed circuit board or an LDS metal structural member, a complex antenna structure may be implemented. When the second antenna sub-portion 92 is a metal plate, a simple antenna structure may be implemented, and costs are low.

In some embodiments, the second antenna sub-portion 92 may alternatively be a conductive heat dissipation member. For example, the second antenna sub-portion 92 may be a graphite sheet, and may be assembled and fastened to the rear cover 2 in a manner of bonding or the like. In this embodiment, the electronic device 100 reuses the heat dissipation member as the second antenna sub-portion 92, so that a heat dissipation function of the heat dissipation member can be retained, and the air duct 5 can also take away heat of the heat dissipation member, so as to take away heat of another component that is in the electronic device 100 and that is connected to the heat dissipation member in a thermally conductive manner, to ensure heat dissipation performance of the electronic device 100. In addition, performance of the antenna 9 of the electronic device 100 can be improved without adding an additional structural member, implementation difficulty is low, and costs are low.

In addition, when the second antenna sub-portion 92 is the graphite sheet, the graphite sheet is easy to be cut, meets a heat dissipation requirement and an antenna design requirement more easily, and has low costs. In some other embodiments, the second antenna sub-portion 92 may alternatively be a conductive heat dissipation member in another form. For example, the second antenna sub-portion 92 may alternatively be a vapor chamber using a heat pipe structure. A specific implementation structure of the second antenna sub-portion 92 is not strictly limited in this embodiment of this application.

In some embodiments, the middle plate 12 of the middle frame 1 may include a metal portion (not shown in the figure), and the metal portion is disposed directly opposite to the first antenna sub-portion 91 and the second antenna sub-portion 92. For example, the middle plate 12 may be entirely made of a metal material, to form the metal portion; or the middle plate 12 may be partially made of a metal material, to form the metal portion.

In this embodiment, the metal portion of the middle plate 12 is disposed directly opposite to the first antenna sub-portion 91 and the second antenna sub-portion 92 and can be used as a reflection plate of the first antenna sub-portion 91 and the second antenna sub-portion 92, to improve radiation efficiency of the antenna 9, adjust a signal direction of the antenna 9, and enhance signal strength of the antenna 9. In addition, the middle plate 12 has the metal portion, so that structural strength of the middle frame 1 can also be increased.

The metal portion may be made of a copper material, an aluminum material, a copper alloy, an aluminum alloy, a copper-aluminum composite material, or the like.

As shown in FIG. 4, in some embodiments, a part of a structure of the support member 7 may form a part of an air duct wall of the air duct 5. In this case, the support member 7 and the air duct 5 are arranged in a compact manner, and a distance between the support member 7 and the air duct 5 is very short. This facilitates coupling between the first antenna sub-portion 91 and the second antenna sub-portion 92, and reduces difficulty in arranging the first antenna sub-portion 91 and the second antenna sub-portion 92. In addition, this also helps save internal space of the electronic device 100, to facilitate miniaturization of the electronic device 100.

For example, a part of the structure of the support member 7 may be in lap joint with the air duct side wall 122, and connects the air duct side wall 122 to the rear cover 2 in a sealed manner.

In some embodiments, the electronic device 100 may further include a first sealing member 20, and the first sealing member 20 is located between the support member 7 and the rear cover 2 and forms a part of the air duct wall of the air duct 5. The first sealing member 20 may be made of a material such as foam or rubber. For example, the first sealing member 20 may be bonded to the support member 7, to maintain a relatively fixed location relationship with the support member 7.

In this embodiment, the first sealing member 20 can seal the air duct 5 and can also limit the support member 7 and the rear cover 2 to provide specific support for the rear cover 2. This helps improve structural reliability of the electronic device 100. In addition, the first sealing member 20 is compressible to some extent and can absorb an assembly tolerance of the support member 7 and the rear cover 2. This helps improve assembly precision of the electronic device 100.

When the second antenna sub-portion 92 extends from the air duct 5 to the inner cavity 4, the first sealing member 20 may also abut against the second antenna sub-portion 92 to perform sealing and limitation. In this case, a part of a structure of the first sealing member 20 is sealed between the support member 7 and the rear cover 2, and the other part of the structure is sealed between the support member 7 and the second antenna sub-portion 92. The second antenna sub-portion 92 is fastened to the rear cover 2, and the first sealing member 20 may abut against but not bonded to the rear cover 2 and the second antenna sub-portion 92, to facilitate disassembly or mounting of the rear cover 2 and the second antenna sub-portion 92. Alternatively, the first sealing member 20 may be bonded and fastened to the rear cover 2 and the second antenna sub-portion 92.

In some embodiments, the electronic device 100 may further include a second sealing member 30, and the second sealing member 30 is located between the support member 7 and the middle frame 1 and forms a part of the air duct wall of the air duct 5. For example, the second sealing member 30 may be sealed between the air duct side wall 122 and the support member 7. The second sealing member 30 may be made of a material such as foam or rubber. For example, the second sealing member 30 may be bonded to the air duct side wall 122 and/or the support member 7, to maintain a stable connection relationship.

In this embodiment, the second sealing member 30 can seal the air duct 5 and can also limit the support member 7 and the middle frame 1. This helps improve structural reliability of the electronic device 100. In addition, the second sealing member 30 is compressible to some extent and can absorb an assembly tolerance of the support member 7 and the middle frame 1. This helps improve assembly precision of the electronic device 100.

When the air duct side wall 122 is made of a metal material, the first sealing member 20 and/or the second sealing member 30 may be made of an insulation material, to implement electrical isolation.

In the embodiment of FIG. 4, the air duct side wall 122, the second sealing member 30, the support member 7, and the first sealing member 20 cooperate to form the air duct wall of the air duct 5. In some other embodiments, the air duct wall of the air duct 5 may also be formed by the air duct side wall 122, or may be formed by the air duct wall, the support member 7, and one of the sealing members. A specific composition structure of the air duct wall of the air duct 5 is not strictly limited in this embodiment of this application.

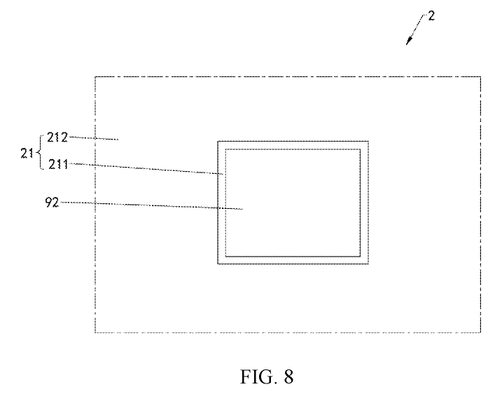

FIG. 7 is a diagram of a partial structure of the electronic device 100 according to an embodiment of this application in some other embodiments, and FIG. 8 is a diagram of a structure of the rear cover 2 of the electronic device 100 shown in FIG. 7 at another angle. A presentation angle of the rear cover 2 in FIG. 8 is a bottom view or a top view of the rear cover 2, that is, a top view of the rear cover 2 from the outside of the electronic device 100 or a bottom view of the rear cover 2 from the inside of the electronic device 100. The electronic device 100 in this embodiment may include most technical features of the electronic device 100 in the foregoing embodiment. The following mainly describes differences between the electronic device 100 in this embodiment and the electronic device 100 in the foregoing embodiment, and a large part of same content between the electronic device 100 in this embodiment and the electronic device 100 in the foregoing embodiment is not described again.

In some embodiments, the electronic device 100 may include the middle frame 1, the rear cover 2, the support member 7, the circuit board 8, and the first antenna sub-portion 91, the rear cover 2 is fastened to one side of the middle frame 1, an inner cavity 4 and an air duct 5 are formed between the rear cover 2 and the middle frame 1, both the support member 7 and the circuit board 8 are mounted in the inner cavity 4, and the first antenna sub-portion 91 is fastened to one side that is of the support member 7 and that faces the rear cover 2, and is electrically connected to the circuit board 8. The rear cover 2 includes a main body 21 and the second antenna sub-portion 92 connected to the main body 21. An arrangement surface of the main body 21 and the second antenna sub-portion 92 is perpendicular to a thickness direction of the rear cover 2, and the main body 21 and the second antenna sub-portion 92 are insulated from each other. At least a part of the second antenna sub-portion 92 is disposed directly opposite to the air duct 5. The first antenna sub-portion 91 is coupled to the second antenna sub-portion 92. The first antenna sub-portion 91 and the second antenna sub-portion 92 jointly form an antenna 9 of the electronic device 100. That is, the antenna 9 of the electronic device 100 includes the first antenna sub-portion 91 and the second antenna sub-portion 92.

In this embodiment, the second antenna sub-portion 92 is additionally disposed in the antenna 9 of the electronic device 100, the second antenna sub-portion 92 is a part of a structure of the rear cover 2 and can perform signal transmission with the outside, and at least a part of the second antenna sub-portion 92 is disposed in correspondence with the air duct 5, so that an area of the antenna is increased by using the air duct 5 of the electronic device 100, performance of the antenna 9 is improved, and the antenna 9 has good bandwidth and radiation efficiency. In addition, the air duct 5 of the electronic device 100 also provides a good clearance environment for the antenna 9. This helps ensure performance of the antenna 9.

It may be understood that a main difference between this embodiment and the foregoing embodiment lies in an implementation of the second antenna sub-portion 92. In the foregoing embodiment, the second antenna sub-portion 92 and the rear cover 2 are two structural members, and the second antenna sub-portion 92 is fastened to the rear cover 2. In this embodiment, the second antenna sub-portion 92 is the part of the structure of the rear cover 2, manufacturing of the second antenna sub-portion 92 is completed when the rear cover 2 is manufactured, and one structural member is reduced compared with the foregoing embodiment. This helps simplify a structure and an assembly process of the electronic device 100.

The rear cover 2 is generally plate-shaped, and a plate surface of the rear cover 2 is perpendicular to the thickness direction of the rear cover 2. An arrangement surface of the main body 21 and the second antenna sub-portion 92 is perpendicular to the thickness direction of the rear cover 2, that is, the main body 21 and the second antenna sub-portion 92 are arranged on the plate surface of the rear cover 2, and the main body 21 and the second antenna sub-portion 92 are also approximately plate-shaped. The rear cover 2 may be in a shape of a flat plate, or the rear cover 2 may be in a shape with a flat central plate and a curved peripheral plate. This is not strictly limited in this embodiment of this application.

A part or all of the structure of the second antenna sub-portion 92 is disposed in correspondence with the air duct 5, that is, in the thickness direction of the electronic device 100, the part or all of the structure of the second antenna sub-portion 92 is disposed directly opposite to the air duct 5. In this case, a projection of the air duct 5 on the rear cover 2 overlaps at least a part of the second antenna sub-portion 92.

The second antenna sub-portion 92 is made of a conductive material. In this embodiment, a part of a region of the rear cover 2 is made of a conductive material, to form a conductive second antenna sub-portion 92, so that the second antenna sub-portion 92 can be used as a part of the antenna 9. The conductive material may be a metal, a carbon fiber, or the like.

In some embodiments, the main body 21 may include an insulation portion 211 and a conductive portion 212. The insulation portion 211 is connected between the second antenna sub-portion 92 and the conductive portion 212. A material of the conductive portion 212 is the same as or different from the material of the second antenna sub-portion 92.

When the material of the conductive portion 212 is the same as the material of the second antenna sub-portion 92, the rear cover 2 may use a structure in which a slit is formed in a conductive structure, and the slit is filled with a non-conductive structure. For example, a slit may be formed in a metal plate body to form the conductive portion 212 and the second antenna sub-portion 92, and the slit is filled with a non-metal material, for example, the insulation portion 211 may be formed through nano-injection molding. In this case, manufacturing costs of the rear cover 2 are low.

When the material of the conductive portion 212 is different from the material of the second antenna sub-portion 92, the material of the second antenna sub-portion 92 is selected more flexibly and can better adapt to an antenna signal transmission requirement.

In some embodiments, the main body 21 is made of an insulation material. In this case, the rear cover 2 may use a structure in which a localized conductive structure is added to an insulation structure. For example, the main body 21 is made of a fiberglass material, the second antenna sub-portion 92 is made of a carbon fiber material, and the rear cover 2 uses a structure in which a localized carbon fiber board is added to the fiberglass board. Alternatively, the main body 21 is made of a plastic material, the second antenna sub-portion 92 is made of a metal material (for example, copper, aluminum, iron, or an alloy thereof), and the rear cover 2 uses a structure in which a localized metal plate is added to a non-metal plate.

The rear cover 2 further includes an appearance layer (not shown in the figure), and the appearance layer may be disposed on one side that is of the main body 21 and the second antenna sub-portion 92 and that faces away from the middle frame 1. For example, the appearance layer may cover a surface that is of the main body 21 and the second antenna sub-portion 92 and that faces away from the middle frame 1. The appearance layer may be configured to protect the rear cover and improve appearance and tactile feel of the rear cover. In addition, the appearance layer also allows signal transmission between the second antenna sub-portion 92 and the outside of the electronic device 100. For example, the appearance layer may be a vegan leather layer or the like.

It may be understood that, main differences between the electronic device 100 in this embodiment and the foregoing embodiment lies in that a structure of the rear cover 2 and composition of the second antenna sub-portion 92 described above are different. For other design content, refer to related descriptions in the foregoing embodiment. Details are not described herein again.

In the foregoing embodiment, a part of a structure of the air duct 5 is formed by the middle frame 1, and the support member 7 is mounted on the middle frame 1. In some other embodiments, a part of a structure of the air duct 5 may alternatively be formed by another structural member of the electronic device 100, and a location of the support member 7 is adaptively adjusted, provided that the support member 7 is still disposed adjacent to the air duct 5. For example, a part of a structure of the air duct 5 may be formed by a support or a support base. The support or the support base is fastened to a non-light-emitting side of the display 3 (that is, one side that is of the display 3 and that faces the rear cover 2), and the support member 7 is also fastened to the non-light-emitting side of the display 3. A composition structure of the air duct 5 and a mounting structure of the support member 7 are not strictly limited in this embodiment of this application.

Reference to "one embodiment", "some embodiments", or the like described in this specification indicates that one or more embodiments of this application include a specific feature, structure, or characteristic described with reference to the embodiments. Therefore, statements such as "in an embodiment", "in some embodiments", and "in some other embodiments" that appear at different places in this specification do not necessarily mean reference to a same embodiment. Instead, the statements mean "one or more but not all of embodiments", unless otherwise specifically emphasized in another manner.

The foregoing descriptions are merely some implementations of this application, but are not intended to limit the protection scope of this application. Any variation or replacement readily figured out by a person skilled in the art within the technical scope disclosed in this application shall fall within the protection scope of this application. When no conflict occurs, embodiments in this application and the features in embodiments may be mutually combined. Therefore, the protection scope of this application shall be subject to the protection scope of the claims.

What is claimed is:

1. An electronic device, comprising:
a middle frame;
a rear cover fastened to one side of the middle frame;
a support member;
a circuit board;
a first antenna sub-portion fastened to one side of the support member and that faces the rear cover, and is electrically connected to the circuit board; and
a second antenna sub-portion fastened to one side of the rear cover and that faces the middle frame, wherein:
an inner cavity and an air duct are defined between the rear cover and the middle frame,
both the support member and the circuit board are mounted in the inner cavity,
the second antenna sub-portion is at least partially located in the air duct,
a region that is of the rear cover and that directly faces the second antenna sub-portion is a non-signal shielding region, and
the first antenna sub-portion and the second antenna sub-portion jointly form an antenna.

2. The electronic device according to claim 1, wherein the second antenna sub-portion is a flexible printed circuit board, a metal member, or a conductive heat dissipation member.

3. The electronic device according to claim 1, wherein the second antenna sub-portion is assembled and fastened to the rear cover, or the second antenna sub-portion is formed on the rear cover.

4. The electronic device according to claim 1, wherein the rear cover is a fiberglass rear cover, a ceramic rear cover, or a plastic rear cover.

5. The electronic device according to claim 1, wherein an area of the second antenna sub-portion is greater than an area of the first antenna sub-portion.

6. The electronic device according to claim 1, wherein:
the second antenna sub-portion is entirely disposed in the air duct; or
the second antenna sub-portion comprises a first part and a second part, the first part is disposed in the air duct, the second part is disposed in the inner cavity, and an area of the first part is greater than an area of the second part.

7. The electronic device according to claim 1, wherein a spacing between the first antenna sub-portion and the second antenna sub-portion is less than one eighth of a wavelength of a center frequency of an operating frequency band of the antenna.

8. The electronic device according to claim 1, wherein:
the support member is an audio module, and the first antenna sub-portion is fastened to an acoustic chamber housing of the audio module; or
the support member is a support, and the first antenna sub-portion is fastened to an insulation part of the support.

9. The electronic device according to claim 1, wherein:
the first antenna sub-portion is a flexible printed circuit board or a metal member;
the first antenna sub-portion is assembled and fastened to the support member; or
the first antenna sub-portion is formed on the support member.

10. The electronic device according to claim 1, wherein a part of a structure of the support member forms a part of an air duct wall of the air duct.

11. The electronic device according to claim 10, further comprising:
a first sealing member located between the support member and the rear cover that forms a part of the air duct wall of the air duct; or
a second sealing member located between the support member and the middle frame that forms a part of the air duct wall of the air duct.

12. The electronic device according to claim 1, wherein the middle frame comprises a frame connected to the rear cover and a middle plate fastened to an inner side of the frame, the middle plate and the rear cover are disposed opposite to each other, the air duct and the inner cavity are located between the middle plate and the rear cover, and an outlet of the air duct is disposed on the frame or disposed between the frame and the rear cover.

13. The electronic device according to claim 12, wherein the middle plate comprises an air duct bottom wall and an air duct side wall, the air duct side wall is fastened to one side of the air duct bottom wall and that faces the rear cover, the air duct side wall is connected to the rear cover, the air duct bottom wall, the air duct side wall, and the rear cover are disposed around the air duct, and the air duct bottom wall and the air duct side wall are integrally formed on the middle plate.

14. The electronic device according to claim 12, wherein the middle plate comprises a metal portion disposed directly opposite to the first antenna sub-portion and the second antenna sub-portion.

15. The electronic device according to claim 1, further comprising a fan mounted in the inner cavity, wherein an air outlet of the fan communicates with the air duct.

16. An electronic device, comprising:
a middle frame;
a rear cover fastened to one side of the middle frame, wherein the rear cover comprises a main body and a second antenna sub-portion connected to the main body, an arrangement surface of the main body and the second antenna sub-portion is perpendicular to a thickness direction of the rear cover, and the main body and the second antenna sub-portion are insulated from each other;
a support member;
a circuit board; and
a first antenna sub-portion fastened to one side of the support member and that faces the rear cover, and is electrically connected to the circuit board,
wherein:
an inner cavity and an air duct are defined between the rear cover and the middle frame,
both the support member and the circuit board are mounted in the inner cavity,
at least a part of the second antenna sub-portion is disposed directly opposite to the air duct, and
the first antenna sub-portion and the second antenna sub-portion jointly form an antenna.

17. The electronic device according to claim 16, wherein the second antenna sub-portion is made of a conductive material.

18. The electronic device according to claim 16, wherein:
the main body comprises a conductive portion and an insulation portion connected between the second antenna sub-portion and the conductive portion, wherein a material of the conductive portion is the same as or different from the material of the second antenna sub-portion; or
the main body is made of an insulation material.
